(19) United States
(12) Patent Application Publication
(10) Pub. No.: US 2022/0302031 A1
(43) Pub. Date: Sep. 22, 2022

(54) SEMICONDUCTOR MEMORY DEVICE AND METHOD OF MANUFACTURING THE SAME

(71) Applicant: Kioxia Corporation, Tokyo (JP)

(72) Inventor: Kosei NODA, Yokkaichi Mie (JP)

(73) Assignee: Kioxia Corporation, Tokyo (JP)

(21) Appl. No.: 17/412,871

(22) Filed: Aug. 26, 2021

(30) Foreign Application Priority Data
Mar. 16, 2021 (JP) 2021-042325

(51) Int. Cl. H01L 23/535; H01L 23/532; H01L 27/11582; H01L 27/11568; H01L 21/768

(52) U.S. Cl. CPC H01L 23/535; H01L 23/53257; H01L 27/11582; H01L 27/11568; H01L 21/76895

(57) ABSTRACT

A semiconductor memory device includes: an upper layer wiring; a stacked body disposed below the upper layer wiring; a pillar penetrating the stacked body; a conductor layer disposed below the stacked body; a lower layer wiring disposed below the conductor layer; and a semiconductor substrate disposed below the lower layer wiring. The conductor layer and the lower layer wirings are electrically connected to each other, and the lower layer wirings and the semiconductor substrate are electrically connected to each other along a path through the upper layer wirings.

### CROSS-REFERENCE TO RELATED APPLICATION

This application is based upon and claims the benefit of priority from Japanese Patent Application No. 2021-042325, filed Mar. 16, 2021, the entire contents of which are incorporated herein by reference.

### FIELD

Embodiments described herein relate generally to a semiconductor memory device and a method of manufacturing the same.

### BACKGROUND

For example, in a semiconductor memory device such as a NAND flash memory, not only a memory cell array including a plurality of pillars but also a circuit for, for example, writing data into the memory cell array are known. The circuit may also be formed at a position below the memory cell array.

### DESCRIPTION OF THE DRAWINGS

FIG. 1 is a block diagram illustrating a configuration example of a memory system according to at least one embodiment;

FIG. 2 is a block diagram illustrating a configuration of a semiconductor memory device according to at least one embodiment;

FIG. 3 is a diagram illustrating an equivalent circuit of the semiconductor memory device according to at least one embodiment;

FIG. 4 is a diagram illustrating a configuration of the semiconductor memory device according to at least one embodiment;

FIG. 5 is a cross-sectional view illustrating the configuration of the semiconductor memory device according to at least one embodiment;

FIG. 6 is a cross-sectional view illustrating the configuration of the semiconductor memory device according to at least one embodiment;

FIG. 7 is a cross-sectional view illustrating the configuration of the semiconductor memory device according to at least one embodiment;

FIG. 8 is a top view illustrating a configuration of the semiconductor memory device according to at least one embodiment;

FIG. 9 is a diagram illustrating an IX-IX cross-section of FIG. 7;

FIG. 10 is a cross-sectional view illustrating a configuration of a semiconductor memory device according to a comparative example;

FIG. 11 is a diagram illustrating a method of manufacturing the semiconductor memory device according to at least one embodiment;

FIG. 12 is a diagram illustrating the method of manufacturing the semiconductor memory device according to at least one embodiment;

FIG. 13 is a diagram illustrating the method of manufacturing the semiconductor memory device according to at least one embodiment;

FIG. 14 is a diagram illustrating the method of manufacturing the semiconductor memory device according to at least one embodiment;

FIG. 15 is a diagram illustrating the method of manufacturing the semiconductor memory device according to at least one embodiment;

FIG. 16 is a diagram illustrating the method of manufacturing the semiconductor memory device according to at least one embodiment;

FIG. 17 is a diagram illustrating the method of manufacturing the semiconductor memory device according to at least one embodiment; and

FIG. 18 is a diagram illustrating a configuration of a modification example.

### DETAILED DESCRIPTION

When arcing occurs during the manufacturing of the semiconductor memory device, for example, during the formation of a memory hole, a part of the circuit may be damaged.

At least one embodiment disclosed provides a semiconductor memory device capable of preventing damage during manufacturing and a method of manufacturing the same.

In general, according to at least one embodiment, there is provided a semiconductor memory device including: an upper layer wiring; a stacked body disposed below the upper layer wiring and including a plurality of first conductor layers stacked in a first direction; a pillar penetrating the stacked body in the first direction and including a semiconductor layer; a charge storage layer disposed between the first conductor layers and the semiconductor layer; a second conductor layer disposed below the stacked body and connected to one end of the semiconductor layer; a lower wiring layer disposed below the second conductor layer and including a lower layer wiring electrically connected to the second conductor layer; and a semiconductor substrate disposed below the lower wiring layer. In the semiconductor memory device, the lower layer wiring and the semiconductor substrate are electrically connected to each other along a path through the upper layer wiring.

Hereinafter, at least one embodiment will be described with reference to the accompanying drawings. For easy understanding of the description, in the drawings, the same components are represented by the same reference numerals, and the description thereof will not be repeated.

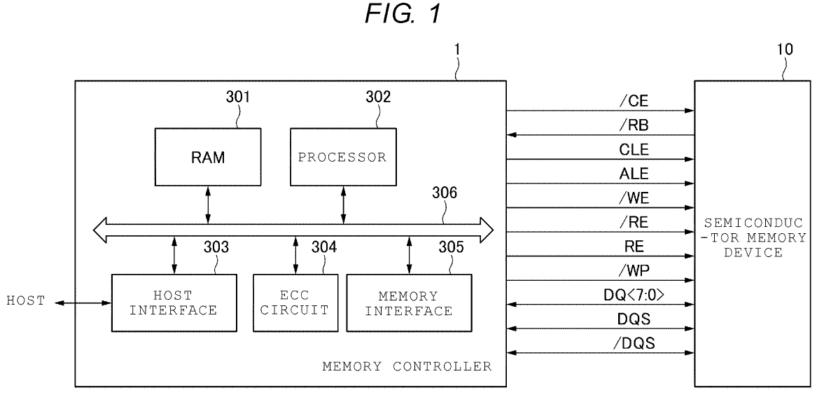

A first embodiment will be described. A semiconductor memory device 10 according to the embodiment is a non-volatile memory device that is configured as a NAND flash memory. In FIG. 1, a configuration example of a memory system including the semiconductor memory device 10 is illustrated as a block diagram. The memory system includes a memory controller 1 and the semiconductor memory device 10. Actually, a plurality of semiconductor memory devices 10 are provided in the memory system in FIG. 1. However, FIG. 1 illustrates only one semiconductor memory device 10. A specific configuration of the semiconductor memory device 10 will be described below. The memory system 1 may be connected to a host (not illustrated). The host is, for example, an electronic apparatus such as a personal computer or a mobile terminal.

The memory controller 1 controls writing of data into the semiconductor memory device 10 according to a write request from the host. The memory controller 1 controls reading of data from the semiconductor memory device 10 according to a read request from the host.

Signals are transmitted and received between the memory controller 1 and the semiconductor memory device 10, the signals including a chip enable signal /CE, a ready/busy signal /RB, a command latch enable signal CLE, an address latch enable signal ALE, a write enable signal /WE, read enable signals RE and /RE, a write-protect signal /WP, a signal DQ<7:0> as data, and data strobe signals DQS and /DQS.

The chip enable signal /CE is a signal for enabling the semiconductor memory device 10. The ready/busy signal /RB is a signal for representing whether the semiconductor memory device 10 is in a ready state or a busy state. “Ready state” refers to a state where the semiconductor memory device 10 can receive a command from an external apparatus. “Busy state” refers to a state where the semiconductor memory device 10 cannot receive a command from an external apparatus. The command latch enable signal CLE is a signal representing that the signal DQ<7:0> is a command. The address latch enable signal ALE is a signal representing that the signal DQ<7:0> is an address. The write enable signal /WE is a signal for taking a received signal into the semiconductor memory device 10, and is asserted every time a command, an address, or data are received by the memory controller 1. The memory controller 1 instructs the semiconductor memory device 10 to take in the signal DQ<7:0> while the signal /WE is at “low (L)” level.

The read enable signals RE and /RE are signals for allowing the memory controller 1 to read data from the semiconductor memory device 10. For example, the signals are used for controlling an operation timing of the semiconductor memory device 10 when the signal DQ<7:0> is output. The write-protect signal /WP is a signal for instructing the semiconductor memory device 10 to prevent data writing and erasing. The signal DQ<7:0> is data that is transmitted and received between the semiconductor memory device 10 and the memory controller 1, and includes a command, an address, and data. The data strobe signals DQS and /DQS are signals for controlling input and output timings of the signal DQ<7:0>.

The memory controller 1 includes a RAM 301, a processor 302, a host interface 303, an ECC circuit 304, and a memory interface 305. The RAM 301, the processor 302, the host interface 303, the ECC circuit 304, and the memory interface 305 are connected to each other via an internal bus 306.

The host interface 303 outputs a request received from the host, user data (write data), or the like via the internal bus 306. The host interface 303 transmits user data read from the semiconductor memory device 10, a response from the processor 302, and the like to the host.

The memory interface 305 controls writing of the user data or the like into the semiconductor memory device 10 and reading of the user data or the like from the semiconductor memory device 10 based on an instruction of the processor 302.

The processor 302 integrally controls the memory controller 1. The processor 302 is, for example, a CPU or an MPU. When the processor 302 receives a request from the host via the host interface 303, the processor 12 executes a control according to the request. For example, the processor 302 instructs the memory interface 305 to write the user data and parity into the semiconductor memory device 10 according to a request from the host. The processor 302 instructs the memory interface 305 to read the user data and parity from the semiconductor memory device 10 according to a request from the host.

The processor 302 determines a storage area (memory area) in the semiconductor memory device 10 for the user data stored in the RAM 301. The user data is stored in the RAM 301 via the internal bus 306. The processor 302 determines the memory area for data (page data) in units of pages that are units of writing. Hereinafter, user data stored in one page of the semiconductor memory device 10 will also be referred to as “unit data”. The unit data is generally encoded and stored in the semiconductor memory device 10 as a code word. In the embodiment, encoding is not essential. The memory controller 1 may store the unit data in the semiconductor memory device 10 without encoding the unit data. FIG. 1 illustrates a configuration in which the unit data is encoded as a configuration example. When the memory controller 1 does not execute encoding, page data matches with unit data. One code word may be generated based on one unit data, and one code word may be generated based on division data in which the unit data is divided. One code word may be generated using a plurality of unit data.

The processor 302 determines a memory area of the semiconductor memory device 10 into which each unit data is to be written. A physical address is assigned to the memory area of the semiconductor memory device 10. The processor 302 manages the memory area into which the unit data is to be written using the physical address. The processor 302 designates the determined memory area (physical address) and instructs the memory interface 305 to write the user data into the semiconductor memory device 10. The processor 302 manages a correspondence between a logical address of the user data (the logical address managed by the host) and the physical address. When the processor 302 receives a read request including the logical address from the host, the processor 12 specifies a physical address corresponding to the logical address, designates the physical address, and instructs the memory interface 305 to read the user data.

The ECC circuit 304 encodes the user data stored in the RAM 301 and generates a code word. The ECC circuit 304 decodes the code word read from the semiconductor memory device 10.

The RAM 301 temporarily stores the user data received from the host until the user data is stored in the semiconductor memory device 10 or temporarily stores data read from the semiconductor memory device 10 until the data is transmitted to the host. The RAM 301 is, for example, a general-purpose memory such as SRAM or DRAM.

FIG. 1 illustrates a configuration example in which the memory controller 1 includes the ECC circuit 304 and the memory interface 305. However, the ECC circuit 304 may be built in the memory interface 305. The ECC circuit 304 may be built in the semiconductor memory device 10. A specific configuration or arrangement of each of the elements shown in FIG. 1 is not particularly limited.

When the memory controller 1 receives a write request from the host 2, the memory system of FIG. 1 operates as follows. The processor 302 temporarily stores data to be written in the RAM 301. The processor 302 reads the data stored in the RAM 301 and inputs the read data into the ECC circuit 304. The ECC circuit 304 encodes the input data and transmits the code word to the memory interface 305. The memory interface 305 writes the input code word into the semiconductor memory device 10.

When the memory controller 1 receives a read request from the host, the memory system of FIG. 1 operates as follows. The memory interface 305 inputs the code word read from the semiconductor memory device 10 to the ECC circuit 304. The ECC circuit 304 decodes the input code word and stores the decoded data in the RAM 301. The processor 302 transmits the data stored in the RAM 301 to the host via the host interface 303.

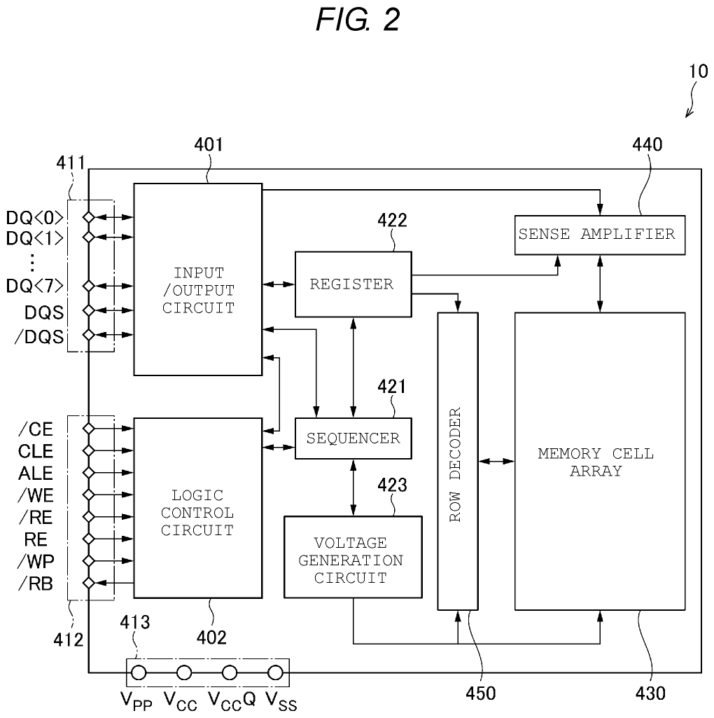

A configuration of the semiconductor memory device 10 will be described below. As illustrated in FIG. 2, the semiconductor memory device 10 includes a memory cell array 430, a sense amplifier 440, a row decoder 450, an input/output circuit 401, a logic control circuit 402, a sequencer 421, a register 422, a voltage generation circuit 423, a pad group for input/output 411, a pad group for logic control 412, and a terminal group for power input 413.

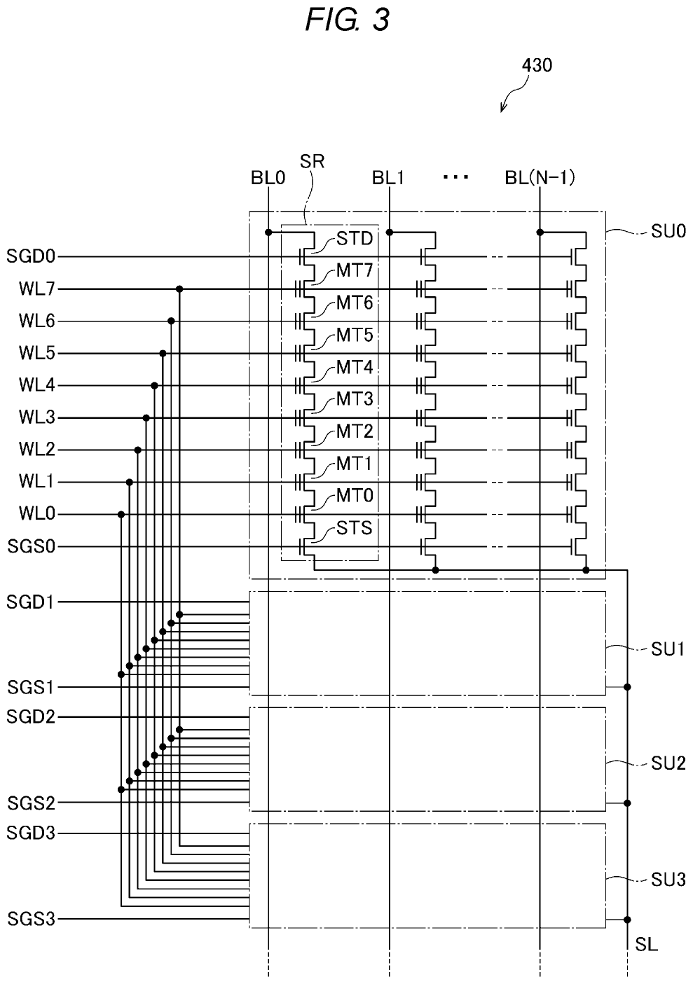

The memory cell array 430 is a portion where data is stored. The memory cell array 430 includes a plurality of memory cell transistors MT correlated with a plurality of bit lines BL and a plurality of word lines WL. A specific configuration of the memory cell array 430 will be described below with reference to FIGS. 3 to 6.

The sense amplifier 440 is a circuit for adjusting a voltage to be applied to the bit line BL or for reading a voltage of the bit line BL and converting the read voltage into data. When data is read, the sense amplifier 440 acquires read data read from the memory cell transistors MT to the bit line BL, and transfers the acquired read data to the input/output circuit 401. When data is written, the sense amplifier 440 transfers write data to be written via the bit line BL to the memory cell transistors MT. An operation of the sense amplifier 440 is controlled by the sequencer 421.

The row decoder 450 is a circuit that is configured as a switch group (not illustrated) to apply a voltage to each of the word lines WL. The row decoder 450 receives a block address and a row address from the register 422, selects a corresponding block based on the block address, and selects a corresponding word line WL based on the row address. The row decoder 450 switches to open and close the switch group such that a voltage is applied from the voltage generation circuit 423 to the selected word line WL. An operation of the row decoder 450 is controlled by the sequencer 421.

The input/output circuit 401 transmits and receives the signal DQ<7:0> and the data strobe signals DQS and /DQS to and from the memory controller 1. The input/output circuit 401 transfers a command and an address in the signal DQ<7:0> to the register 422. The input/output circuit 401 transmits and receives write data and read data to and from the sense amplifier 440.

The logic control circuit 402 receives the chip enable signal /CE, the command latch enable signal CLE, the address latch enable signal ALE, the write enable signal /WE, the read enable signals RE and /RE, and the write-protect signal /WP from the memory controller 1. The logic control circuit 402 transfers the ready/busy signal /RB to the memory controller 1 and notifies a state of the semiconductor memory device 10 to an external apparatus.

The sequencer 421 controls operations of the respective units including the memory cell array 430 based on control signals input from the memory controller 1 to the input/output circuit 401 and the logic control circuit 402.

The register 422 is a portion that temporarily stores a command or an address. The register 422 stores a command for instructing a write operation, a read operation, an erasing operation, or the like. The command is input from the memory controller 1 to the input/output circuit 401 and subsequently is transferred from the input/output circuit 401 to the register 422 and stored therein.

The register 422 also stores an address corresponding to the command. The address is input from the memory controller to the input/output circuit 401 and subsequently is transferred from the input/output circuit 401 to the register 422 and stored therein.

The register 422 also stores status information representing an operation state of the semiconductor memory device 10. The status information is updated every time by the sequencer 421 according to the operation state of the memory cell array 430 or the like. The status information is output from the input/output circuit 401 to the memory controller 1 as a state signal in response to a request from the memory controller 1.

The voltage generation circuit 423 is a portion that generates a voltage required for each of the write operation, the read operation, and the erasing operation of data in the memory cell array 430. Examples of the voltage include a voltage to be applied to each of the word lines WL and a voltage to be applied to each of the bit lines BL. An operation of the voltage generation circuit 423 is controlled by the sequencer 421.

The pad group for input/output 411 is a portion where a plurality of terminals (pads) are provided that transmit and receive the respective signals between the memory controller 1 and the input/output circuit 401. The respective terminals are provided individually corresponding to the signal DQ<7:0> and the data strobe signals DQS and /DQS.

The pad group for logic control 412 is a portion where a plurality of terminals (pads) are provided that transmit and receive the respective signals between the memory controller 1 and the logic control circuit 402. The respective terminals are provided individually corresponding to the chip enable signal /CE, the command latch enable signal CLE, the address latch enable signal ALE, the write enable signal /WE, the read enable signals RE and /RE, the write-protect signal /WP, and the ready/busy signal /RB.

The terminal group for power input 413 is a portion where a plurality of terminals are provided that receive application of each of the voltages required for the operation of the semiconductor memory device 10. The voltages to be applied to the respective terminals include power supply voltages Vcc, VccQ, and Vpp and a ground voltage Vss.

The power supply voltage Vcc is a circuit power supply voltage that is supplied from an external apparatus as an operating power, for example, a voltage of about 3.3 V. The power supply voltage VccQ is, for example, a voltage of 1.2 V. The power supply voltage VccQ is a voltage that is used when the signals are transmitted and received between the memory controller 1 and the semiconductor memory device 10. The power supply voltage Vpp is higher than the power supply voltage Vcc, for example, a voltage of 12 V.

A specific configuration of the memory cell array 430 will be described. In FIG. 3, the configuration of the memory cell array 430 is illustrated as an equivalent circuit diagram. As illustrated in the drawing, the memory cell array 430 includes a plurality of string units SU0 to SU3. Each of the string units SU0 to SU3 includes a plurality of cell strings SR. Each of the cell strings SR includes, for example, eight memory cell transistors MT0 to MT7 and two select transistors STD and STS. The number of memory cell transistors or select transistors in the cell string SR may be different from that in the example of FIG. 1.

The string units SU0 to SU3 are configured with one block as a whole, and a plurality of blocks are provided in the memory cell array 430. In FIG. 3, only the single block is illustrated, and other blocks are not illustrated.

In the following description, the string units SU0 to SU3 will also be referred to as “string unit SU” without being distinguished from each other. Likewise, the memory cell transistors MT0 to MT7 will also be referred to as “memory cell transistor MT” without being distinguished from each other.

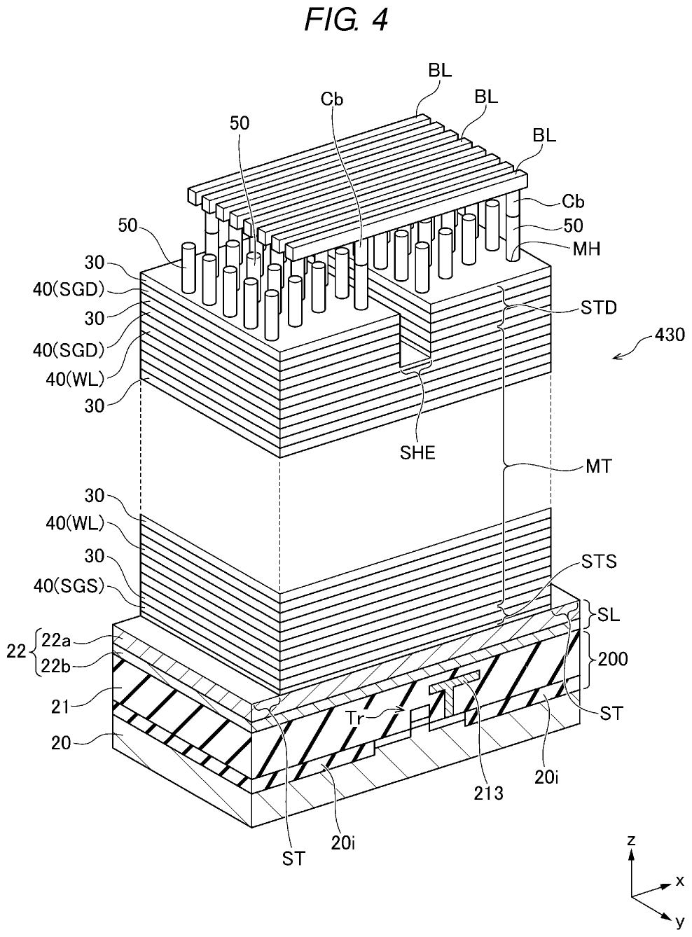

Each of the string units Su includes the same number of cell strings SR as an N number of bit lines BL0 to BL(N-1). N is a positive integer. The cell string SR is formed such that the memory cell transistors MT0 to MT7 and the select transistors STD and STS are arranged in series. As described below, the cell string SR is formed along a pillar 50 provided inside a memory hole MH illustrated in FIG. 4 or the like. The pillar 50 is a columnar body having a substantially cylindrical shape and will also be referred to as “memory pillar”.

The memory cell transistors MT0 to MT7 in the cell string SR are arranged in series between a source of the select transistor STD and a drain of the select transistor STS. A drain of the select transistor STD is connected to any one of the bit lines BL0 or the like. A source of the select transistor STS is connected to a source line SL. In the following description, the bit lines BL1 to BL(N-1) will also be referred to as “bit line BL” without being distinguished from each other.

As described below, each of the memory cell transistors MT is configured as a transistor including a charge storage layer in a gate portion. The amount of charge stored in the charge storage layer corresponds to data stored in the memory cell transistors MT. The memory cell transistor MT may be, for example, a charge trap type in which a silicon nitride film or the like is used as the charge storage layer, and the charge storage layer may be, for example, a floating gate type in which a silicon film or the like is used.

All the gates of the select transistors STD in the string unit SU0 are connected to a select gate line SGD0. The select gate line SGD0 is a line to which a voltage for switching to open and close each of the select transistors STD is applied. As in the string units SU1 to SU3, select gate lines SGD1 to SGD3 corresponding to the respective string units SU are provided that apply a voltage to the select transistor STD.

All the gates of the select transistors STS in the string unit SU0 are connected to a select gate line SGS0. The select gate line SGS0 is a line to which a voltage for switching to open and close each of the select transistors STS is applied. As in the string units SU1 to SU3, select gate lines SGS1 to SGS3 corresponding to the respective string units SU are provided that apply a voltage to the select transistor STS. The select gate line SGS is shared between the string units SU0 to SU3 configuring one block, and gates of all the select transistors STS in the string units SU0 to SU3 may be connected to a common select gate line SGS.

Respective gates of the memory cell transistors MT0 to MT7 are connected to the word lines WL0 to WL7. The word lines WL0 to WL7 are lines to which a voltage is applied, for example, in order to switch to open and close the memory cell transistors MT0 to MT7 or to change the amount of charge stored in each of the charge storage layers in the memory cell transistors MT0 to MT7.

Data in the semiconductor memory device 10 is collectively written and read per unit called “page” into and from the memory cell transistors MT connected to any one of the word lines WL in any one of the string units SU. On the other hand, data in the semiconductor memory device 10 is collectively erased from all the memory cell transistors MT in the block. Since various well-known methods may be adopted as specific methods for the operations of writing, reading, and erasing data, the detailed description thereof will not be repeated.

In FIG. 4, configurations of the memory cell array 430 in the semiconductor memory device 10 and a portion in the vicinity thereof are illustrated as a schematic perspective view. As illustrated in the same drawing, the semiconductor memory device 10 includes a semiconductor substrate 20, an insulator layer 21, a conductor layer 22, and a plurality of insulator layers 30 and conductor layers 40.

The semiconductor substrate 20 is a plate-shaped member including a flat surface on a side in a z direction in FIG. 4 and is, for example, a silicon wafer. The insulator layer 21, the conductor layer 22, the insulator layers 30, the conductor layers 40, and the like form a film including a plurality of layers formed on an upper surface side of the semiconductor substrate 20, for example, by CVD deposition. For example, an element isolation region 20i is provided on the surface of the semiconductor substrate 20. The element isolation region 20i is, for example, an insulating region including a silicon oxide, and a part of the element isolation region 20i is a portion that separates a source region and a drain region of a transistor Tr.

The insulator layer 21 is a layer formed of an insulating material such as silicon oxide. On the surface side of the semiconductor substrate 20, for example, the transistor Tr and a peripheral circuit 200 including a lower layer wiring 213 or the like described below are formed. The peripheral circuit 200 configures the sense amplifier 440, the row decoder 450, and the like illustrated in FIG. 2. The insulator layer 21 covers the entirety of the peripheral circuit 200.

The conductor layer 22 is a layer functioning as the source line SL in FIG. 3. The conductor layer 22 is formed of a layer of a material including silicon, for example, polycrystalline silicon doped with impurity, or a metal layer. The conductor layer 22 is buried in the insulator layer 21 in a portion below the memory cell array 430. The conductor layer 22 is disposed below the cell string SR and corresponds to “second conductor layer” in the embodiment.

The entirety of the conductor layer 22 may be formed of a semiconductor material such as silicon. However, as in the case of FIG. 4, the conductor layer 22 may have a two-layer structure including a semiconductor layer 22a and a conductive layer 22b. The semiconductor layer 22 is a layer formed of a semiconductor material such as silicon, and the conductive layer 22b is a layer formed of a metal material such as tungsten.

The insulator layers 30 and the conductor layers 40 are formed above the conductor layer 22 and are alternately arranged in the z direction of FIG. 4.

The conductor layers 40 are conductive layers formed of, for example, a material including tungsten. The respective conductor layers 40 are used as the word lines WL0 to WL7, the select gate lines SGS1 and SGD1, and the like in FIG. 3. Each of the insulator layers 30 is disposed at a position between the conductor layers 40 adjacent to each other and electrically insulates the conductor layers 40 from each other. The insulator layers 30 are formed of, for example, a material including silicon oxide. The conductor layers 40 correspond to “first conductor layers” in the embodiment.

In a region the insulator layers 30 and the conductor layers 40 are stacked in the z direction, a plurality of memory holes MH penetrate the region in the z direction, and the pillar 50 having a substantially cylindrical shape is formed inside each of the memory holes MH. Each of the pillars 50 is formed in a region from the insulator layer 30 on the outermost side in the z direction to the conductor layer 22.

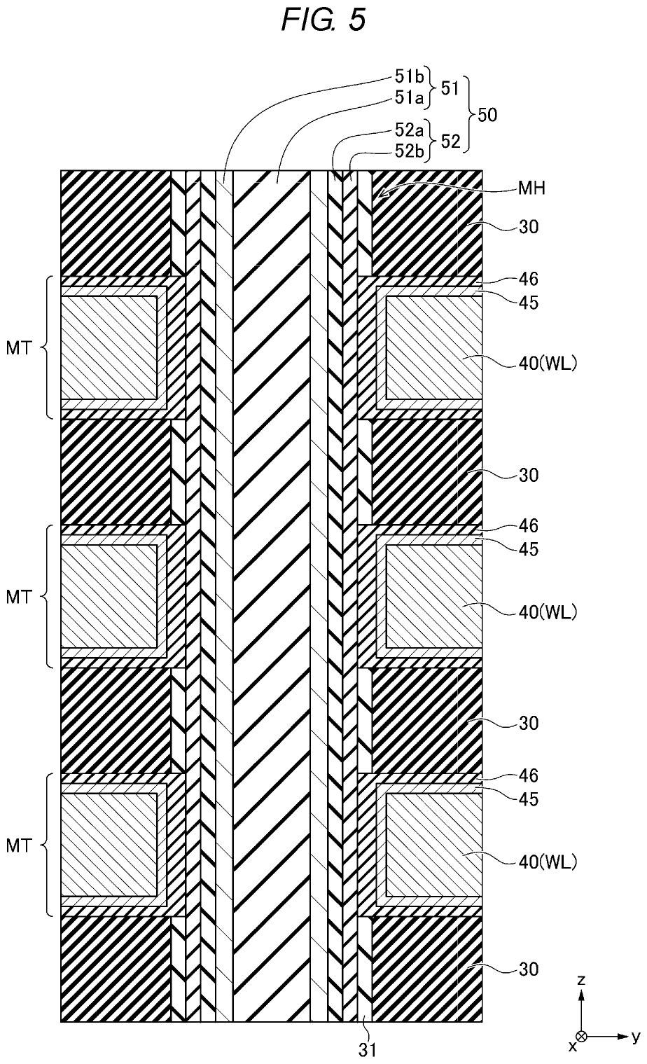

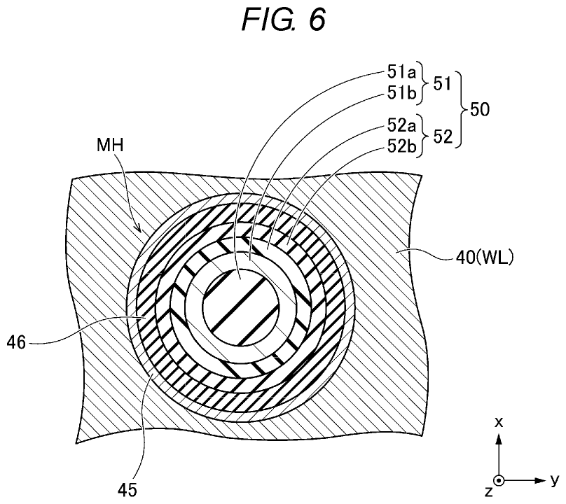

In FIG. 5, a cross-section of the pillar 50 taken along a surface (y-z plane) passing through a central axis in a longitudinal direction thereof is illustrated. In FIG. 6, a cross-section of the cell string SR taken along a surface (x-y plane) that is perpendicular to a central axis of the cell string SR and passes through the conductor layer 40.

As illustrated in FIG. 6, the pillar 50 has a circular or elliptical cross-sectional shape. The pillar 50 includes a body 51 and a stacked film 52.

The body 51 includes a core portion 51a and a semiconductor layer 51b. The semiconductor layer 51b is formed of, for example, a material formed of amorphous silicon, and is a portion where a channel such as the memory cell transistor MT is formed. The core portion 51a is formed of, for example, an insulating material such as silicon oxide, and is provided inside the semiconductor layer 51b. The entirety of the body 51 may be configured to be the semiconductor layer 51b such that the core portion 51a on the inside is not provided.

The stacked film 52 is a film including a plurality of layers that cover an outer circumference of the body 51. The stacked film 52 includes, for example, a tunnel insulating film 52a and a charge trap film 52b. The tunnel insulating film 52a is a film that is formed on the innermost side. The tunnel insulating film 52a includes, for example, silicon oxide or silicon oxide and silicon nitride. The tunnel insulating film 52a is a potential barrier between the body 51 and the charge trap film 52b. For example, when electrons are implanted from the body 51 into the charge trap film 52b (write operation) and when holes are injected from the body 51 into the charge trap film 52b (erasing operation), the electrons and the holes pass (tunneling) through the potential barrier of the tunnel insulating film 52a. A block insulating film surrounding the outside of the charge trap film 52b may be provided as a part of the stacked film 52. The block insulating film may be formed of, for example, silicon oxide. When the block insulating film is provided as a part of the stacked film 52, a block insulating film 46 described below does not need to be provided.

The charge trap film 52b is a film that covers the outside of the tunnel insulating film 52a. The charge trap film 52b includes, for example, silicon nitride and includes a trap site where charge is trapped. A portion of the charge trap film 52b interposed between the conductor layer 40 as the word line WL and the body 51 configures the storage area of the memory cell transistor MT as the charge storage layer described above. A threshold voltage of the memory cell transistor MT changes depending on the presence of charge in the charge trap film 52b or the amount of charge. As a result, the memory cell transistor MT stores information.

In at least one embodiment, the charge trap film is adopted as the charge storage layer. However, the embodiment is not limited thereto. For example, by adopting a floating gate structure, a configuration where a floating gate is disposed as the charge storage layer between the gate (conductor layer 40) and the channel (semiconductor layer 51b) may be adopted. Here, a configuration where the floating gate is not provided in the pillar 50 may also be adopted.

As illustrated in FIG. 5, an outer circumferential surface of the conductor layer 40 as the word line WL is covered with a barrier film 45 and a block insulating film 46. The barrier film 45 is a film for improving adhesion between the conductor layer 40 and the block insulating film 46. For example, when the conductor layer 40 is tungsten, a film having a stacked structure of titanium nitride and titanium is selected as the barrier film 45.

The block insulating film 46 is a film for preventing charge back tunneling from the conductor layer 40 to the stacked film 52 side. The block insulating film 46 is, for example, a silicon oxide film or a metal oxide film. One example of the metal oxide is aluminum oxide (AlOx).

A cover insulating film 31 is provided between the insulator layer 30 and the charge trap film 52b. The cover insulating film 31 includes, for example, silicon oxide. The cover insulating film 31 is a film for protecting the charge trap film 52b from being etched in a replacement step of replacing a sacrificing layer with the conductor layer 40. When the replacement step is not used for forming the conductor layer 40, the cover insulating film 31 does not need to be provided.

As described above, a portion where the pillar 50 and the conductor layer 40 intersects with each other functions as a transistor. That is, an array of the intersections between the pillars 50 and the conductor layers 40 form the cell string SR illustrated in FIG. 3, and are in a state where a plurality of transistors are connected in series along the longitudinal direction of the pillars 50. Each of the conductor layers 40 functions as the word line WL, and functions as a gate of each of the transistors. The semiconductor layer 51b functions as a channel of the transistor.

Some of the transistors arranged in series along the longitudinal direction of the pillars 50 as described above function as the memory cell transistors MT in FIG. 3. The transistors formed on both sides of the memory cell transistors MT arranged in series function as the select transistors STD and STS in FIG. 3.

Referring to FIG. 4 again, the description will be continued. As illustrated in the drawing, a plurality of bit lines BL are provided above the pillars 50. The respective bit lines BL are formed as linear wirings that extend in an x direction of FIG. 4, and are arranged in a y direction in the same drawing. An upper end of the pillar 50 is connected to anyone of the bit lines BL through a contact Cb. As a result, the semiconductor layer 51b of each of the pillars 50 is electrically connected to the bit line BL.

In a lower end portion of the pillar 50, the stacked film 52 is removed, and the semiconductor layer 51b is connected to the conductor layer 22. As a result, the conductor layer 22 functioning as the source line SL is electrically connected to the channel of each of the transistors.

The conductor layer 40 and the insulator layer 30 that are stacked are divided into a plurality of portions by slits ST. The slits ST are linear grooves extending in the y direction of FIG. 4 and, for example, are formed up to a depth reaching the conductor layer 22. An inner surface of the slit ST is filled with an insulating material (not illustrated).

An upper side portion of the conductor layer 40 and the insulator layer 30 that are stacked is divided by a slit SHE. The slit SHE is a shallow groove that extends in the y direction in FIG. 4. The slit SHE is formed up to a depth such that at least a portion of the conductor layers 40 that is provided as the select gate line SGD is divided. The inside of the slit SHE is filled with an insulating material (not illustrated). When only one string unit SU is provided between a pair of slits ST, the slit SHE does not need to be provided.

Hereinafter, configurations of the respective units will be described using the x direction, the y direction, and the z direction illustrated in FIG. 4. The z direction is a direction from the lower side toward the upper side and is a direction in which the conductor layers 40 are stacked. The x direction is a direction intersecting with the z direction and is a direction in which each of the bit lines BL extends. The y direction is a direction intersecting with both of the z direction and the x direction and is a direction in which the bit lines BL are arranged.

As described above, in the semiconductor memory device 10 according to at least one embodiment, the semiconductor substrate 20 is disposed below the conductor layer 22 as the source line layer, and the peripheral circuit 200 is formed at a position below the conductor layer 22. Such configuration is also called CMOS under array (CUA).

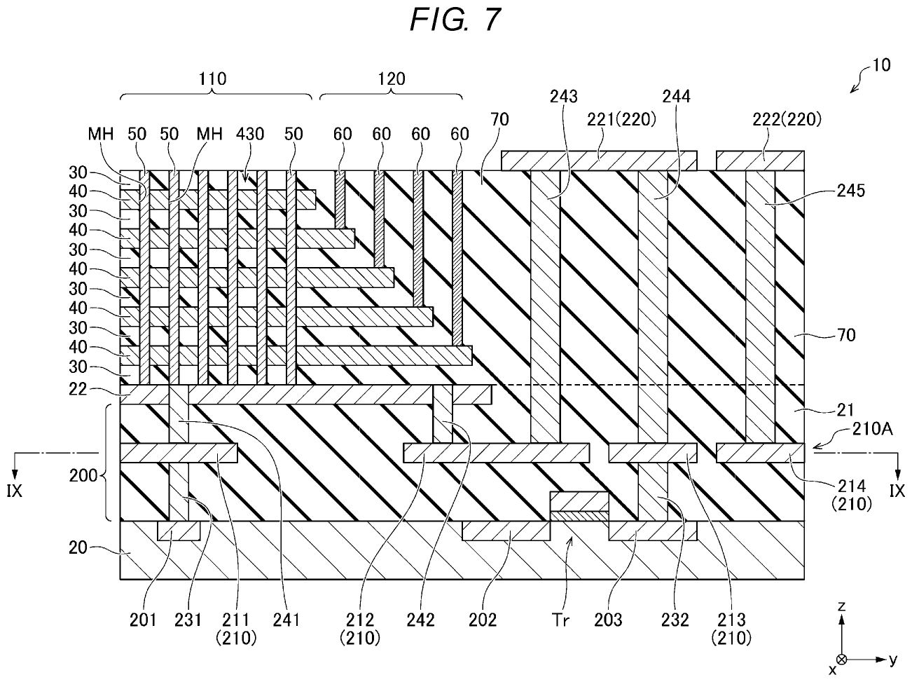

In FIG. 7, configurations of the peripheral circuit 200 in the semiconductor memory device 10 and the vicinity thereof are schematically illustrated. In the same drawing, in a region represented by reference numeral “110”, as described above with reference to FIG. 5, the pillars 50 penetrate the conductor layers 40 such that the memory cell array 430 is configured. Hereinafter, the region where the pillars 50 are provided will also be referred to as “cell region 110”.

In a region (region represented by reference numeral “120” in FIG. 7) on the side of the cell region 110 in the y direction, each of the conductor layers 40 stacked in the cell region 110 are drawn out stepwise toward the side in the y direction. In the region, the conductor layers 40 are formed stepwise. Therefore, a part (terrace portion) of the conductor layers 40 is exposed to the side in the z direction without being blocked by the other conductor layers 40.

Each of the conductor layers 40 exposed as described above is connected to an end portion of a contact 60 extending in the z direction. The contact 60 is a columnar member that is formed of, for example, a material including a conductor such as tungsten. With such configuration, voltage application or the like can be individually executed on the respective conductor layers 40 used as the word lines WL0 to WL7, the select gate lines SGS1 and SGD1, and the like through each of the contacts 60. Hereinafter, the region where each of the conductor layers 40 is drawn out stepwise will also be referred to as “stepwise region 120”. The stepwise region 120 may be provided not only on the side in the y direction of the cell region 110 but also on the sides in the y direction and the −y direction of the cell region 110.

The periphery of the conductor layers 40 or the contacts 60 in the stepwise region 120 is buried with an insulator 70. The insulator 70 is, for example, silicon oxide. In the embodiment, the insulator layer 21, the insulator layers 30, and the insulator 70 are formed of the same silicon oxide, and boundary portions thereof are integrated. In FIG. 7, a boundary between the insulator layer 21 and the insulator 70 is represented by a dotted line.

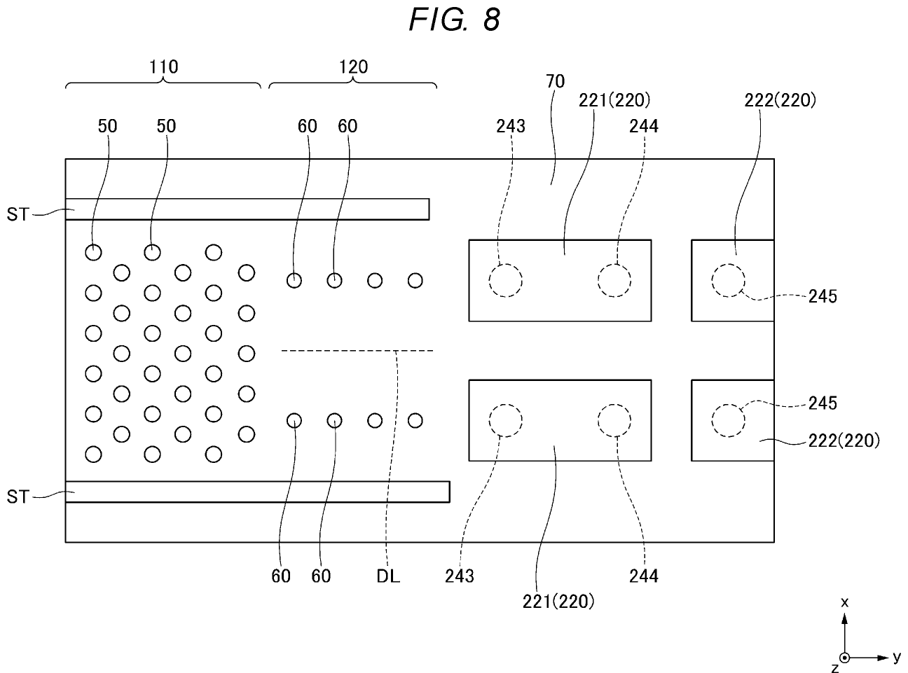

In FIG. 8, a portion of the semiconductor memory device 10 illustrated in FIG. 7 is schematically illustrated in a top view. As illustrated in FIG. 8, the pair of slits ST extend over a range including the entirety of the cell region 110 and the stepwise region 120 in the y direction. At a position on the side in the x direction further than the slit ST on the side in the x direction among the pair of slits ST illustrated in FIG. 8, the cell region 110 and the stepwise region 120 configuring another block may be provided. Likewise, at a position on the side in the −x direction further than the slit ST on the side in the −x direction, the cell region 110 and the stepwise region 120 configuring another block may be provided.

A plurality of contacts 60 in the stepwise region 120 are arranged to be divided into one row on the side in the x direction and another row on the side in the −x direction as illustrated in FIG. 8.

For example, when conductor layers 40 present in an upper portion among the conductor layers 40 are drawn out stepwise to a portion of the stepwise region 120 on the side in the x direction further than a dotted line DL and conductor layers 40 present in a lower portion among the conductor layers 40 are drawn out stepwise to a portion of the stepwise region 120 on the side in the −x direction further than the dotted line DL (that is, when a so-called “multi-row structure” is adopted), the contacts 60 may be disposed in two rows as illustrated in FIG. 8. In FIG. 7, in order to avoid complication, the conductor layers 40 in the stepwise region 120 are schematically illustrated to be stepwise in the simple one row instead of the multi-row structure described above.

Next, the configuration of the peripheral circuit 200 and the like will be described mainly with reference to FIGS. 7 and 8. The peripheral circuit 200 includes the transistor Tr, a plurality of lower layer wirings 210, and a plurality of upper layer wirings 220.

On the surface of the semiconductor substrate 20, a plurality of circuit elements (not illustrated) such as transistors or capacitors are formed, and the transistor Tr in FIG. 7 is one of the circuit elements. The transistor Tr is provided that adjusts the potential of the conductor layer 22 as the source line SL. On the surface of the semiconductor substrate 20, a pair of SD regions 202 and 203 configuring the source region or the drain region of the transistor Tr are formed. The SD region 203 is electrically connected to the conductor layer 22 through a contact 244 described below or the like. The SD region 202 is connected to another circuit element of the peripheral circuit 200 through a wiring (not illustrated).

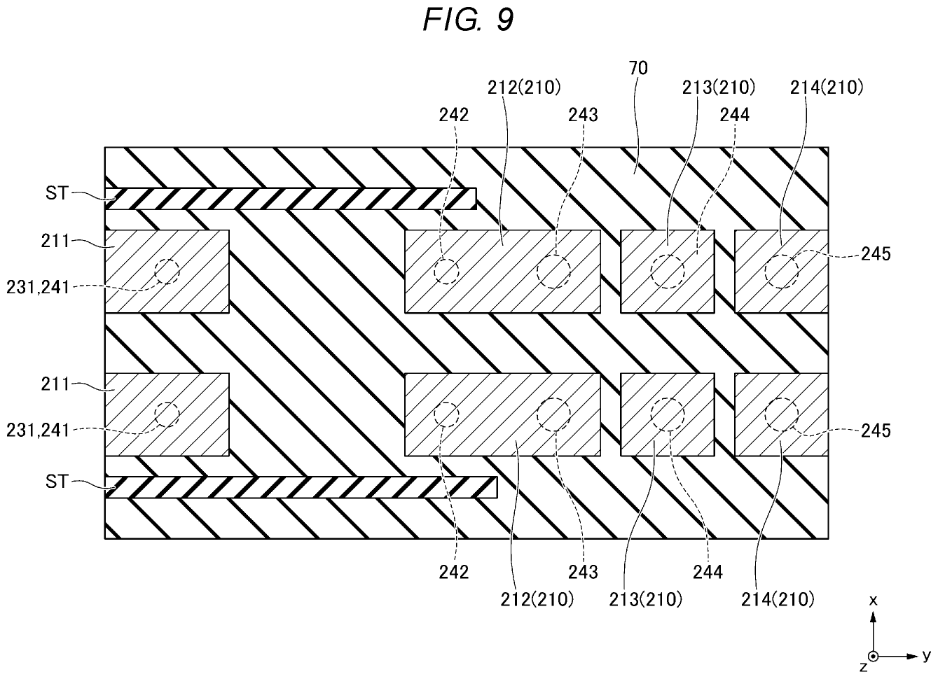

The lower layer wirings 210 are provided in a lower wiring layer 210A formed at a position below the conductor layer 22 (second conductor layer). The lower layer wirings 210 are formed, for example, a conductive material such as tungsten. In FIG. 7, lower layer wirings 211, 212, 213, and 214 among the lower layer wirings 210 are illustrated. The lower layer wirings 211, 212, 213, and 214 are formed at the same height position in the z direction. The lower layer wirings 210 may include layer wirings at a height position different from that of the lower layer wirings 211, 212, 213, and 214. In either case, the lower layer wirings 210 are disposed at positions below the conductor layer 22 and above the semiconductor substrate 20. As illustrated in FIG. 9 illustrating an IX-IX cross-section of FIG. 7, in the embodiment, the lower layer wirings 211, 212, 213, and 214 are provided in pairs, and each pair of the lower layer wirings 211 and the like are arranged in the x direction.

As illustrated in FIG. 7, the entirety of the lower layer wirings 211 is disposed at a position below the conductor layer 22. The lower layer wirings 211 and the conductor layer 22 are electrically connected to each other through an AC plug 241. The lower layer wirings 211 and the semiconductor substrate 20 are electrically connected to each other through a contact 231. The AC plug 241 and the contact 231 are formed of, for example, a conductive material such as tungsten, and linearly extend in the z direction.

By doping a part of the surface of the semiconductor substrate 20 with impurity, an N-type well region 201 is formed. The contact 231 is connected to the N-type well region 201 in the semiconductor substrate 20.

At least the periphery of the N-type well region 201 in the semiconductor substrate 20 is formed of a P-type semiconductor. Therefore, the N-type well region 201 and the P-type portion in the periphery thereof configure one diode as a whole. Therefore, the contact 231 is connected to the semiconductor substrate 20 through the diode including the N-type well region 201.

Even when a voltage is applied to the conductor layer 22 as the source line SL, a voltage in the opposite direction is applied to the diode. Therefore, in a normal condition other than a state where arcing occurs described below, a current does not flow between the conductor layer 22 and the semiconductor substrate 20. As a result, a predetermined potential is maintained in the conductor layer 22.

A part of the lower layer wirings 212 is disposed at a position below the conductor layer 22. The other part of the lower layer wirings 212 extend up to a position outside the conductor layer 22 in a top view. The lower layer wirings 212 and the conductor layer 22 are electrically connected to each other through an AC plug 242. As in the AC plug 241, the AC plug 242 are formed of, for example, a conductive material such as tungsten, and linearly extend in the z direction. The materials of the AC plugs 241 and 242 may be polysilicon instead of a metal material. The portion of the lower layer wirings 212 that extends up to a position outside the conductor layer 22 in a top view is electrically connected to upper layer wirings 221 through a contact 243 described below.

The entirety of the lower layer wirings 213 is disposed at a position outside the conductor layer 22 in a top view. The lower layer wirings 212 and the SD region 203 of the semiconductor substrate 20 are electrically connected to each other through a contact 232. The contact 232 is formed of, for example, a conductive material such as tungsten, and linearly extends in the z direction.

As in the lower layer wirings 213, the entirety of the lower layer wirings 214 is disposed at a position outside of the conductor layer 22 in a top view. The lower layer wirings 214 are electrically connected to upper layer wirings 222 through a contact 245 described below.

The upper layer wirings 220 are wiring layers formed at a position above the pillar 50. The upper layer wirings 220 are formed, for example, a conductive material such as tungsten. In FIG. 7, upper layer wirings 221 and 222 among the upper layer wirings 220 are illustrated. The upper layer wirings 221 and 222 are formed at the same height position in the z direction. The upper layer wirings 220 may include layer wirings at a height position different from that of the upper layer wirings 221 and 222. In either case, the upper layer wirings 220 are wiring layers disposed at a position above the pillar 50. As illustrated in FIG. 8, in the embodiment, the upper layer wirings 221 and 222 are provided in pairs, and each pair of the upper layer wirings 221 and the like are arranged in the x direction.

In a top view, a part of the upper layer wirings 221 is disposed at a position overlapping the lower layer wirings 212, and another part of the upper layer wirings 221 is disposed at a position overlapping the lower layer wirings 213. The upper layer wirings 221 and the lower layer wirings 212 are electrically connected to each other through the contact 243. The upper layer wirings 221 and the lower layer wirings 213 are electrically connected to each other through the contact 244. The contacts 243 and 244 are formed of, for example, a conductive material such as tungsten, and linearly extend in the z direction. In a region where the contact 243 is formed, the upper layer wirings 221 and the lower layer wirings 212 overlap each other in a top view. Ina region where the contact 244 is formed, the upper layer wirings 221 and the lower layer wirings 213 overlap each other in a top view.

In a top view, a part of the upper layer wirings 222 is disposed at a position overlapping the lower layer wirings 214. The upper layer wirings 222 and the lower layer wirings 214 are electrically connected to each other through the contact 245. The contact 245 is formed of, for example, a conductive material such as tungsten, and linearly extends in the z direction. In a region where the contact 245 is formed, the upper layer wirings 221 and the lower layer wirings 214 overlap each other in a top view.

As described above, in the semiconductor memory device 10 according to the embodiment, the conductor layer 22 and the lower layer wirings 212 are electrically connected to each other, and the lower layer wirings 212 and the semiconductor substrate 20 are electrically connected to each other along a path through the upper layer wirings 221. Specifically, “the path through the upper layer wirings 221” is a path passing through the contact 232, the lower layer wirings 213, the contact 244, the upper layer wirings 221, and the contact 243. In the embodiment, the upper layer wirings 221 and the semiconductor substrate 20 are electrically connected to each other through the transistor Tr formed on the surface of the semiconductor substrate 20 (specifically, through the SD region 203). As a result, a voltage to be applied to the conductor layer 22 can be adjusted through the opening and closing operation of the transistor Tr.

As a path for applying a voltage to the conductor layer 22, for example, a wiring formed by filling the inside of the slit ST with a conductor material can be considered to be used. However, in such configuration, the degree of freedom of the width or the arrangement of the slit ST is limited, and thus it may be difficult to reduce the size of the semiconductor memory device 10. On the other hand, in the embodiment, it is not necessary to use the slit ST as the electrical path described above, and thus the size of the semiconductor memory device 10 can be reduced.

As described above, the path for applying a voltage to the conductor layer 22 includes the contacts 243 and 244 that electrically connect the lower layer wirings 210 and the upper layer wirings 220. In the embodiment, when seen in a direction (that is, the z direction) perpendicular to the surface of the semiconductor substrate 20, both of the contacts 243 and 244 are provided at a position outside the cell region 110 and the stepwise region 120.

At such position, the contacts 243 and 244 do not need to penetrate the conductor layers 40 or the conductor layer 22. Since the contacts 243 and 244 and the conductor layers 40 and the like do not need to be electrically insulated from each other, the contacts 243 and 244 can be easily formed.

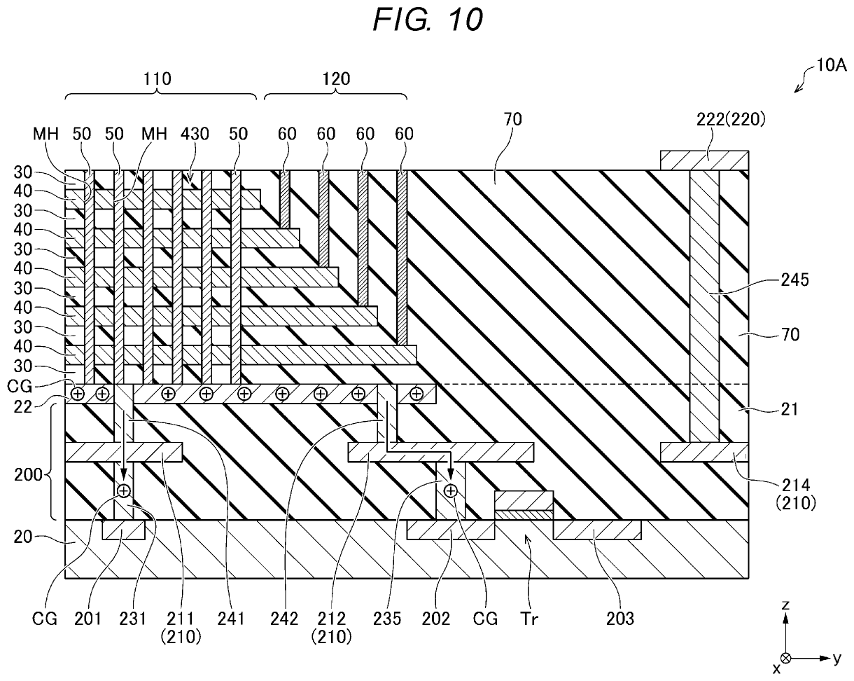

In FIG. 10, a configuration of a semiconductor memory device 10A according to a comparative example is schematically illustrated using the same method as that of FIG. 7. In the comparative example, the lower layer wirings 212 and the semiconductor substrate 20 are electrically connected directly through a contact 235 instead of through the upper layer wirings 220. The contact 235 is formed of, for example, a conductive material such as tungsten, and linearly extends in the z direction. An upper end of the contact 235 is connected to the lower layer wirings 212, and a lower end of the contact 235 is connected to the SD region 202. In the configuration, as in the embodiment, the voltage to be applied to the conductor layer 22 can be adjusted using the transistor Tr.

However, in the configuration of the comparative example, during the manufacturing of the semiconductor memory device 10A, there may be a problem in that the transistor Tr and the like are damaged by arcing.

During the manufacturing of the semiconductor memory device 10A, the formation of the peripheral circuit 200 on the lower side is executed first, and subsequently, the formation of the memory holes MH on the upper side is executed. As is well-known, the memory holes MH are formed, for example, by anisotropic etching using reactive ion etching (RIE).

When the memory holes MH are formed up to a position reaching the conductor layer 22 by anisotropic etching, charge CG is stored in the conductor layer 22 by ions used for the etching. When the amount of charge CG stored is excessively large, the charge CG moves along a path indicated by arrows in FIG. 10 such that arcing may occur toward the semiconductor substrate 20.

Here, in the diode formed in the N-type well region 201, a voltage exceeding a breakdown voltage is applied, and a current flows to the semiconductor substrate 20 through the diode. The AC plug 241 and the N-type well region 201 are assumed and formed in advance as a path where a current generated by arcing flows, and thus is not damaged by arcing.

In the comparative example, during the formation of the memory holes MH, the lower layer wirings 212 and the semiconductor substrate 20 are connected to each other through the contact 235. Therefore, a part of the charge CG stored in the conductor layer 22 reaches the transistor Tr through the contact 235. That is, a current generated by arcing flows along a path through the transistor Tr. As a result, the transistor Tr configuring the peripheral circuit 200 and other circuit elements connected to the transistor Tr may be damaged by overcurrent. Therefore, in the embodiment, by manufacturing the semiconductor memory device 10 using the following method, the above-described problem is solved.

The method of manufacturing the semiconductor memory device 10 will be described. The semiconductor memory device 10 is manufactured through a circuit formation step, a stacking step, a step formation step, a pillar formation step, a replacement step, and a connection step.

<Circuit Formation Step>

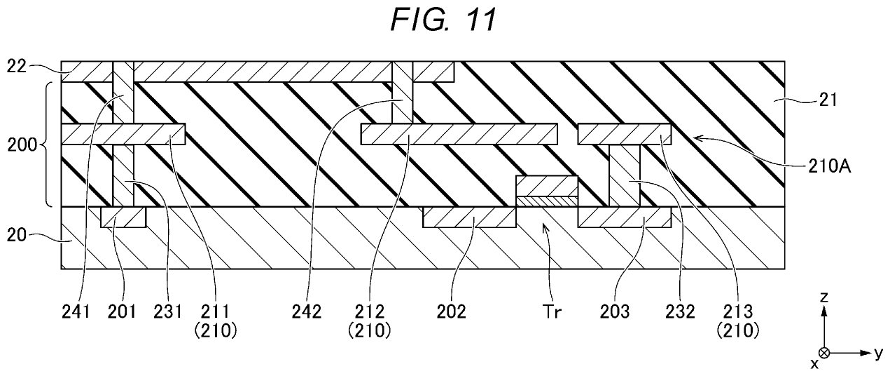

In the circuit formation step, circuit elements such as the transistor Tr are formed on the surface of the semiconductor substrate 20. Next, for example, the insulator layer 21 that cover the circuit elements are formed, for example, by CVD deposition. The conductor layer 22 is formed in an upper portion in the insulator layer 21. The insulator layer 21 is formed to be divided into a plurality of layers, and the lower layer wirings 210 are formed to extend along gaps between the layers. Here, the contacts 231 and 232 that connect the lower layer wirings 210 and the semiconductor substrate 20 to each other and the AC plugs 241 and 242 that connect the lower layer wirings 210 and the conductor layer 22 are also formed. In the circuit formation step, the peripheral circuit 200, the insulator layer 21 with which the periphery is buried, and the conductor layer 22 are formed using the above-described method. FIG. 11 illustrates a state where the circuit formation step is completed. It can be said that the circuit formation step is a step of forming the lower layer wirings 210 and the conductor layer 22 above the semiconductor substrate 20, the conductor layer 22 being electrically connected to the lower layer wirings 210.

In the circuit formation step, a diffusion preventing film for preventing diffusion of hydrogen from above may be provided at a height position between the conductor layer 22 and the lower layer wirings 210. As the diffusion preventing film, for example, a film formed of silicon nitride may be used.

<Stacking Step>

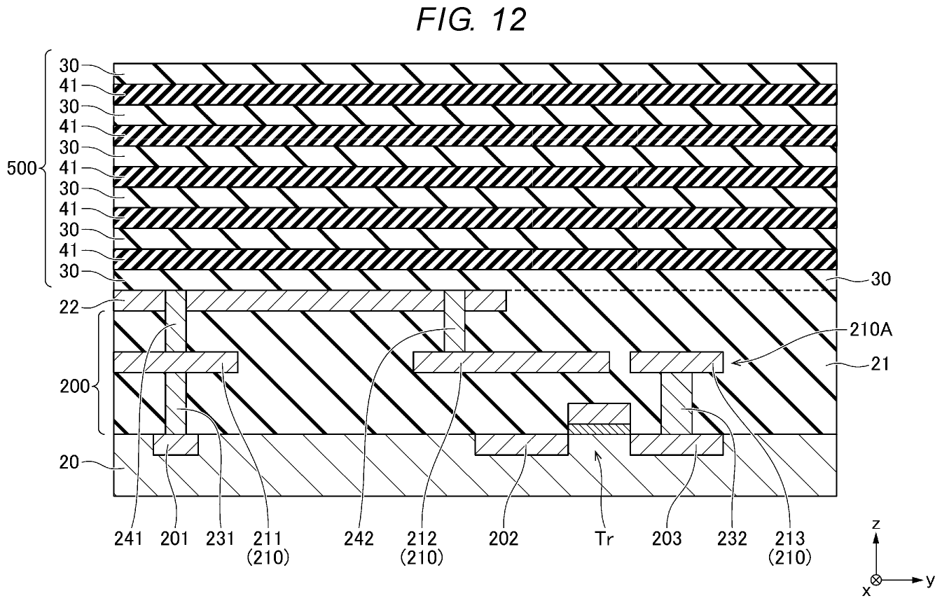

The stacking step is executed after the circuit formation step. In the stacking step, a stacked body 500 is formed to cover the conductor layer 22 and the entire periphery thereof from above. The stacked body 500 is a layer in which a plurality of insulator layers 30 and a sacrificing layer 41 are alternately stacked in the z direction. The sacrificing layer 41 is a layer to be replaced with the conductor layers 40 in the replacement step below. As the sacrificing layer 41, for example, silicon nitride is used. The stacked body 500 is formed, for example, by CVD film formation. FIG. 12 illustrates a state where the stacking step is completed. It can be said that the stacking step is a step of forming the stacked body 500 above the conductor layer 22.

<Step Formation Step>

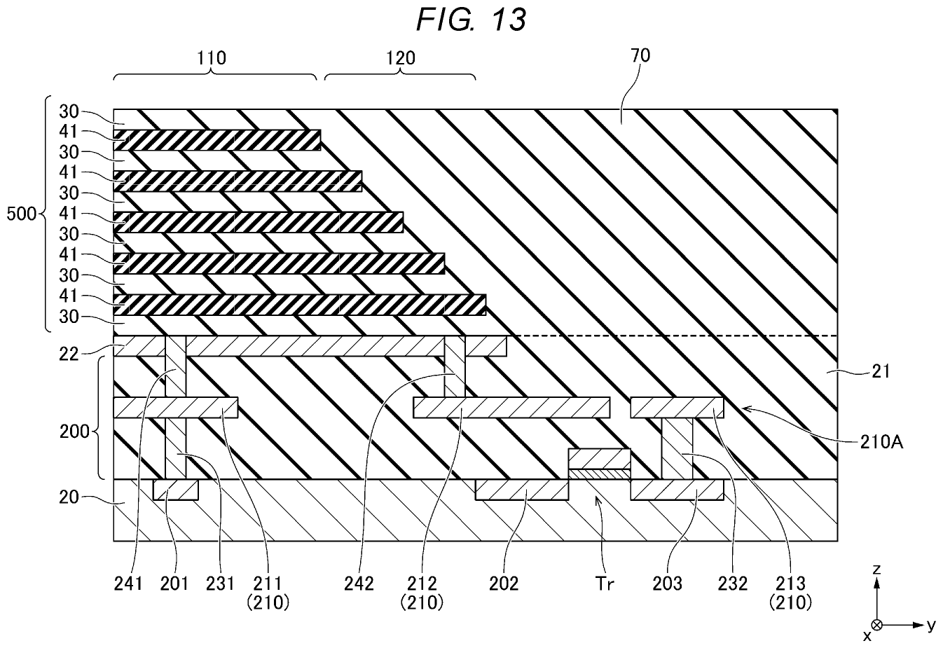

The step formation step is executed after the stacking step. In the step formation step, a part of the stacked body 500 is formed stepwise by repeating anisotropic etching and slimming of an etching mask. In the stacked body 500, the portion that is processed stepwise forms the stepwise region 120, and the other portion forms the cell region 110. Next, the periphery of the portion that is processed stepwise is buried with the insulator 70. As described above, the insulator 70 is formed of the same silicon oxide as that of the insulator layer 21 and the insulator layers 30, and integrated with the insulator layer 21 and the insulator layers 30. FIG. 13 illustrates a state where the step formation step is completed.

<Pillar Formation Step>

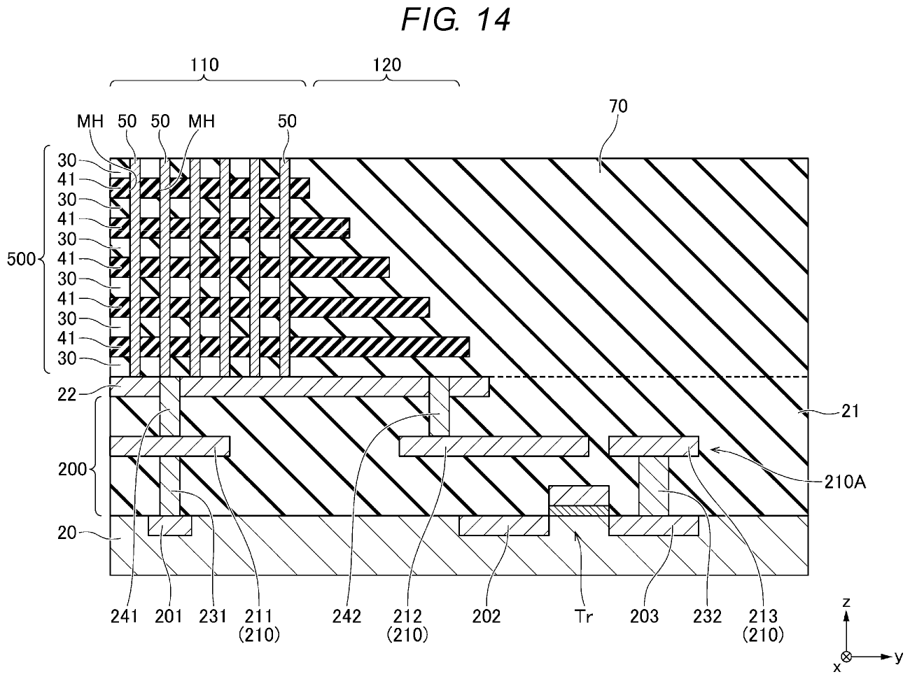

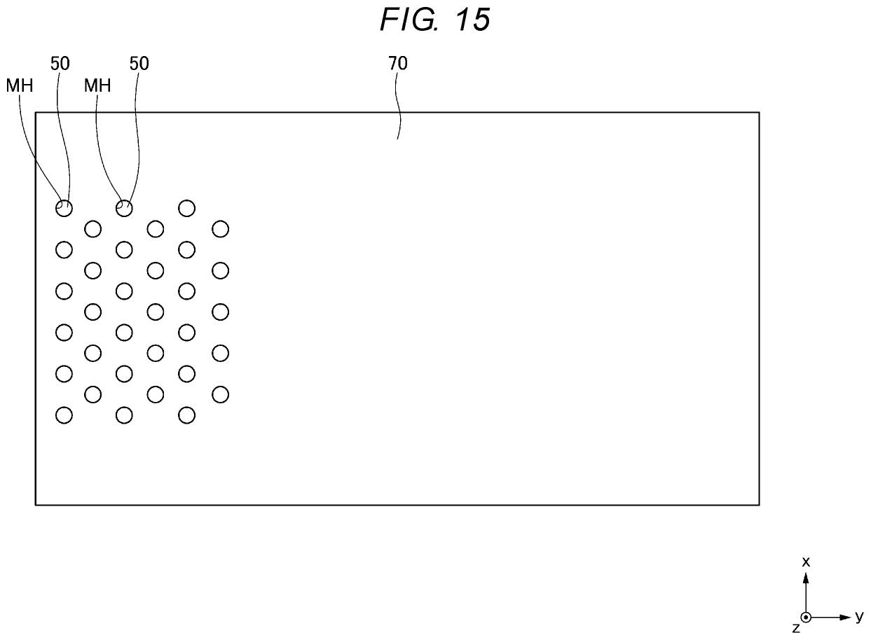

The pillar formation step is executed after the step formation step. In the pillar formation step, a plurality of memory holes MH are formed in the portion of the cell region 110 in the stacked body 500, for example, by RIE. Next, the pillars 50 are formed, for example, by CVD film formation such that the inside of the memory holes MH are buried with the pillars 50. FIGS. 14 and 15 illustrate a state where the pillar formation step is completed. It can be said that the pillar formation step is a step of forming the pillars 50 to penetrate the stacked body 500.

As in the comparative example described above with reference to FIG. 10, when the memory holes MH are formed, the charge CG may be stored in the conductor layer 22 by ions used for the etching. However, when the pillar formation step according to the embodiment is executed, the contacts 243 and 244 and the like are not yet formed. Therefore, the conductor layer 22 and the transistor Tr are not electrically connected to each other. Therefore, the charge CG stored in the conductor layer 22 flows to the semiconductor substrate 20 only along the path through the AC plug 241, the lower layer wirings 211, and the contact 231. As such, in the embodiment, even when arcing occurs during manufacturing, a current does not flow along a path through the transistor Tr. Therefore, damages to the transistor Tr and the like can be reliably prevented.

<Replacement Step>

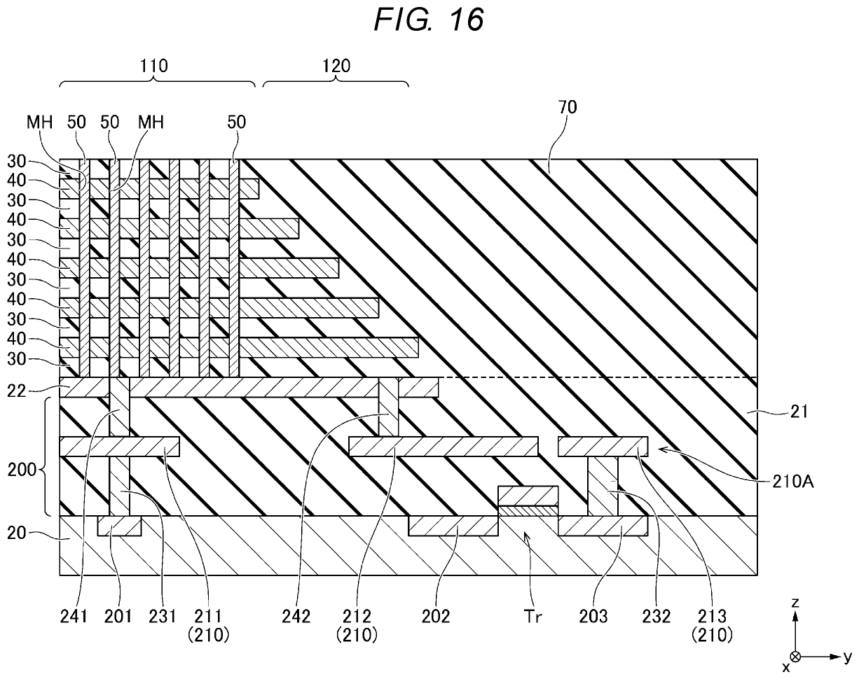

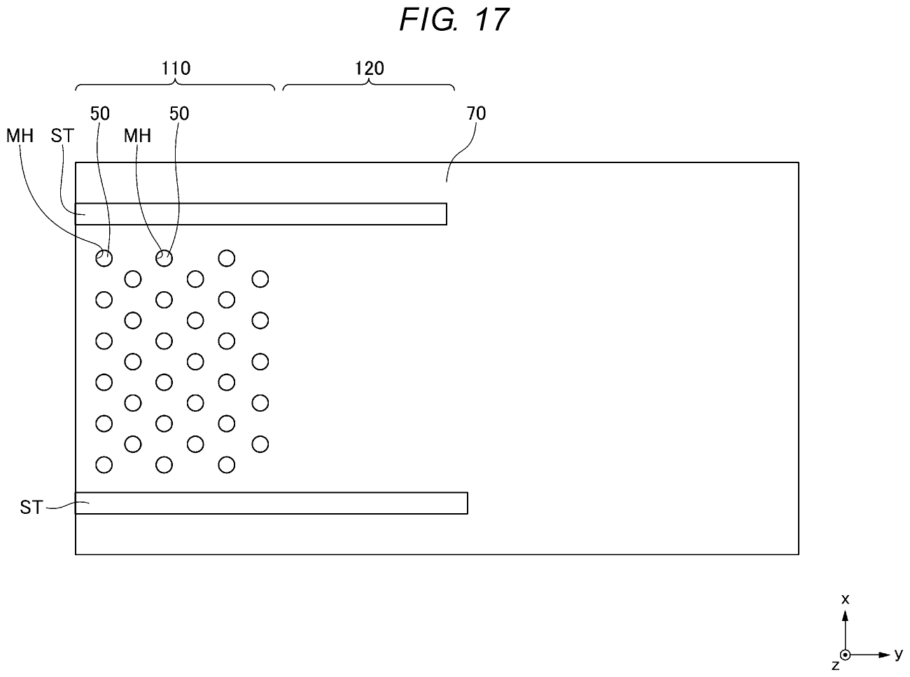

The replacement step is executed after the pillar formation step. In the replacement step, a pair of slits ST are formed such that the cell region 110 and the stepwise region 120 are interposed therebetween. The slits ST are formed up to a depth reaching the conductor layer 22, for example, by RIE. Next, the sacrificing layer 41 is removed by wet etching through the slits ST. Next, the conductor layers 40 are formed on the portion where the sacrificing layer 41 is present, for example, by CVD. As such, in the replacement step, the sacrificing layer 41 is replaced with the conductor layers 40. After completion of the replacement step, the inside of the slits ST is filled with an insulating material. FIGS. 16 and 17 illustrate a state where the replacement step is completed.

<Connection Step>

The connection step is executed after the replacement step. In the connection step, the contacts 243, 244, and 245 are formed by forming a hole penetrating the insulator 70 in the z direction, for example, by RIE and burying the hole with a conductive material. Next, the upper layer wirings 220 are formed, for example, by CVD film formation. As a result, as illustrated in FIG. 7, the lower layer wirings 212 and the lower layer wirings 213 are electrically connected to each other through the contacts 243 and 244 and the upper layer wirings 221. In the connection step, the contact 243 and the like are formed as described above, and the contact 60 is also formed using the same method. It can be said that the connection step is a step of electrically connecting the lower layer wirings 212 and the semiconductor substrate 20 to each other through the upper layer wirings 221 disposed above the pillars 50. After the connection step, the bit lines BL and the like are formed using the same method as that of the related art, and the semiconductor memory device 10 illustrated in FIGS. 4 and 7 is completed.

As described above, in the embodiment, after forming the memory holes MH in the pillar formation step, the conductor layer 22 and the transistor Tr are electrically connected to each other in the connection step. As a result, damages to the transistor Tr by arcing can be prevented.

In the embodiment, the contact 243 that connects the lower layer wirings 212 and the upper layer wirings 221, and the contact 244 that connects the upper layer wirings 221 and the lower layer wirings 213 are formed in a region different from both of the cell region 110 and the stepwise region 120. The position where the contacts 243 and 244 are formed may be different from that of the embodiment.

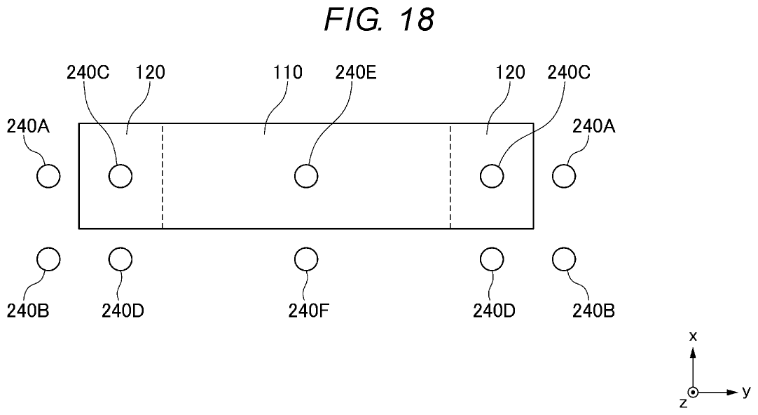

FIG. 18 illustrate a plurality of examples of the position where at least one of the contacts 243 and 244 is formed in the drawing schematically illustrating the cell region 110 and the pair of stepwise regions 120 positioned on both sides of the cell region 110 in a top view.

A position represented by reference numeral “240A” in the same drawing is a position where the contacts 243 and 244 are formed in a region different from both of the cell region 110 and the stepwise region 120 as in the embodiment. The position of the region different from both of the cell region 110 and the stepwise region 120 is not limited to the position represented by reference numeral “240A” and may be any one of positions represented by reference numerals “240B”, “240D”, and “240F”.

The contacts 243 and 244 may be formed inside the stepwise region 120, for example, as in a position represented by reference numeral “240C”. The contacts 243 and 244 may be formed inside the cell region 110, for example, as in a position represented by reference numeral “240E”. Here, the contact 243 and the like are connected to the lower layer wirings 210 through the conductor layers 40 or the conductor layer 22. Therefore, it is necessary that the periphery of the contact 243 and the like is surrounded by an insulating material.

For example, when the contact 243 and the like are formed, after forming an insulating film on an inner surface of a hole formed by RIE, the inside of the insulating film may be buried with a conductive material. After forming a hole in a predetermined region (region including the contact 243 and the like) in a top view and burying the hole with an insulating material, the contact 243 and the like may be formed to penetrate the insulating material in the z direction.

After forming the stacked body 500 and allowing the sacrificing layer 41 to remain in a partial region as it is without replacing the sacrificing layer 41 in the replacement step, the contact 243 and the like may be formed to penetrate the partial region in the z direction. In order to allow the sacrificing layer 41 to remain in the partial region as it is, for example, the replacement step may be executed, for example, after forming a pair of slits between which the region is to be interposed in advance and burying the slits with an insulating material.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device comprising:
an upper layer wiring;
a stacked body disposed below the upper layer wiring, the stacked body including a plurality of first conductor layers stacked in a first direction;
a pillar penetrating the stacked body in the first direction, the pillar including a semiconductor layer;
a charge storage layer disposed between the plurality of first conductor layers and the semiconductor layer;
a second conductor layer disposed below the stacked body, the second conductor layer connected to one end of the semiconductor layer;
a lower wiring layer disposed below the second conductor layer, the lower wiring layer including a lower layer wiring electrically connected to the second conductor layer; and
a semiconductor substrate disposed below the lower wiring layer, wherein
the lower layer wiring and the semiconductor substrate are electrically connected to each other through the upper layer wiring.

2. The semiconductor memory device according to claim 1, further comprising a contact configured to electrically connect the lower layer wiring and the upper layer wiring to each other,
wherein, in a direction perpendicular to a surface of the semiconductor substrate, the contact does not overlap with the pillar.

3. The semiconductor memory device according to claim 1, wherein a transistor is disposed on a surface of the semiconductor substrate, the transistor electrically connecting the upper layer wiring and the semiconductor substrate to each other.

4. The semiconductor memory device according to claim 1, wherein the stacked body includes insulating layers alternating with the first conductor layers.

5. The semiconductor memory device according to claim 4, wherein the insulating layers include silicon oxide.

6. The semiconductor memory device according to claim 4, wherein the first conductor layers include tungsten.

7. The semiconductor memory device according to claim 1, wherein the charge storage layer includes a charge trap layer.

8. The semiconductor memory device according to claim 7, wherein the charge trap layer includes silicon nitride.

9. The semiconductor memory device according to claim 1, wherein the second conductor layer includes silicon.

10. The semiconductor memory device according to claim 1, wherein the second conductor layer has a two layer structure.

11. The semiconductor memory device according to claim 1, wherein the lower layer wiring includes a plurality of lower layer wirings.

12. The semiconductor memory device according to claim 11, wherein the lower layer wirings are at a same height.

13. The semiconductor memory device according to claim 11, wherein the lower layer wirings are electrically connected to the first conductor layers via conductive plugs.

14. The semiconductor memory device according to claim 11, wherein the lower layer wirings are electrically connected to the semiconductor substrate via conductive plugs.

15. A method of manufacturing a semiconductor memory device, the method comprising:
forming a lower layer wiring and a conductor layer above a semiconductor substrate, the conductor layer being electrically connected to the lower layer wiring;
forming a stacked body above the conductor layer;
forming a pillar that penetrates the stacked body; and
electrically connecting the lower layer wiring and the semiconductor substrate through an upper layer wiring disposed above the pillar.

16. The method according to claim 15, wherein the pillar includes a semiconductor layer.

17. The method according to claim 15, further comprising forming a contact configured to electrically connect the lower layer wiring and the upper layer wiring to each other.

18. The method according to claim 15, wherein the lower layer wiring includes a plurality of lower layer wirings.
